(19) United States
(12) Patent Application Publication
(10) Pub. No.: US 2025/0284946 A1
(43) Pub. Date: Sep. 11, 2025

(54) COMPLEMENTARY METAL-OXIDE SEMICONDUCTOR (CMOS) BASED RESISTIVE PROCESSING UNIT WITH ASYMMETRIC UPDATE

(71) Applicant: International Business Machines Corporation, Armonk, NY (US)

(72) Inventors: YULONG LI, Hartsdale, NY (US); TAYFUN GOKMEN, Briarcliff Manor, NY (US); Malte Johannes Rasch, Chappaqua, NY (US); Takashi Ando, Eastchester, NY (US); Babar Khan, Ossining, NY (US)

(21) Appl. No.: 18/596,605

(22) Filed: Mar. 5, 2024

(51) Int. Cl. G06N 3/063; H03K 19/20

(52) U.S. Cl. CPC G06N 3/063; H03K 19/20

(57) ABSTRACT

A resistive processing unit to accelerate neural network training through asymmetric weight update. The resistive processing unit includes a readout field-effect transistor and a transmission gate circuit, the transmission gate circuit being coupled to a selectable first voltage source and including a first transmission gate and a second transmission gate, and having at least one transistor gate coupled to a second voltage source. A capacitor is coupled to the transmission gate circuit and is coupled to the readout field-effect transistor. An input of an inverter is coupled to at least one gate of the first transmission gate and an output of the inverter is coupled to at least one gate of the first transmission gate.

### BACKGROUND

The present invention relates generally to the electrical, electronic and computer arts and, more particularly, to machine learning and resistive processing unit circuits and methods.

Machine learning hardware innovation calls for an analog weight update component that meets preset specifications to accommodate the learning speed requirement for deep neural network applications. Stochastic gradient descent and back propagation is a conventional algorithm that is widely used to train neural networks, and which contains forward, backward and weight update cycles. A resistive processing unit (RPU) has been proposed to achieve parallel operation within forward, backward, and update cycles, respectively, which greatly accelerate the neural network training process.

### BRIEF SUMMARY

Principles of the invention provide systems and techniques for a CMOS-based resistive processing unit with asymmetric update. In one aspect, a resistive processing unit to accelerate neural network training through asymmetric weight update comprises a readout field-effect transistor; a transmission gate circuit, the transmission gate circuit being coupled to a selectable first voltage source and including a first transmission gate and a second transmission gate, having at least one transistor gate coupled to a second voltage source; a capacitor coupled to the transmission gate circuit and coupled to the readout field-effect transistor; and an inverter, an input of the inverter being coupled to at least one gate of the first transmission gate and an output of the inverter being coupled to at least one gate of the first transmission gate.

In one aspect, a system comprises a plurality of first stochastic pulse lines; a plurality of second stochastic pulse lines; a plurality of update voltage lines; a plurality of readout voltage lines; an array of capacitor-based resistive processing units, each capacitor-based resistive processing unit connected to one of the plurality of first stochastic pulse lines, one of the plurality of second stochastic pulse lines, one of the plurality of update voltage lines and one of the plurality of readout voltage lines; and a controller, the controller configured to update capacitor voltages of the capacitor-based resistive processing units in parallel during a weight update phase and wherein a collection of readout current from the capacitor-based resistive processing units emulates a matrix multiplication operation during a readout phase.

In one aspect, an exemplary method includes the operations of setting a selectable first voltage source based on a given weight update, for an array as described; generating a first stochastic pulse and a second stochastic pulse to apply the given weight update to a weight capacitor based on the setting of the selectable first voltage source; and setting the selectable first voltage source to indicate an idle state.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:

a capacitor-based RPU that supports asymmetric weight updates;

a capacitor-based RPU that serves as the building block of an RPU array which achieves parallel weight updates, and set/reset and readout operations;

as compared to existing complementary metal oxide semiconductor (CMOS)-based RPU cell designs emphasizing symmetric weight update, avoid requirement for a complicated control circuit and advantageously handle updated specifications for an RPU; and/or

a capacitor-based RPU that supports a high number of states and a high signal-to-noise ratio (SNR).

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 is a circuit diagram for an example capacitor-based RPU unit cell, in accordance with example embodiments;

FIG. 2 is circuit diagram for a 2×2 capacitor-based RPU array, in accordance with example embodiments;

FIG. 3 illustrates the results of simulating the capacitor-based RPU of FIG. 1, in accordance with example embodiments;

FIG. 4 depicts a computing environment according to an embodiment of the present invention (e.g., for implementing a design process such as that of FIG. 5); and

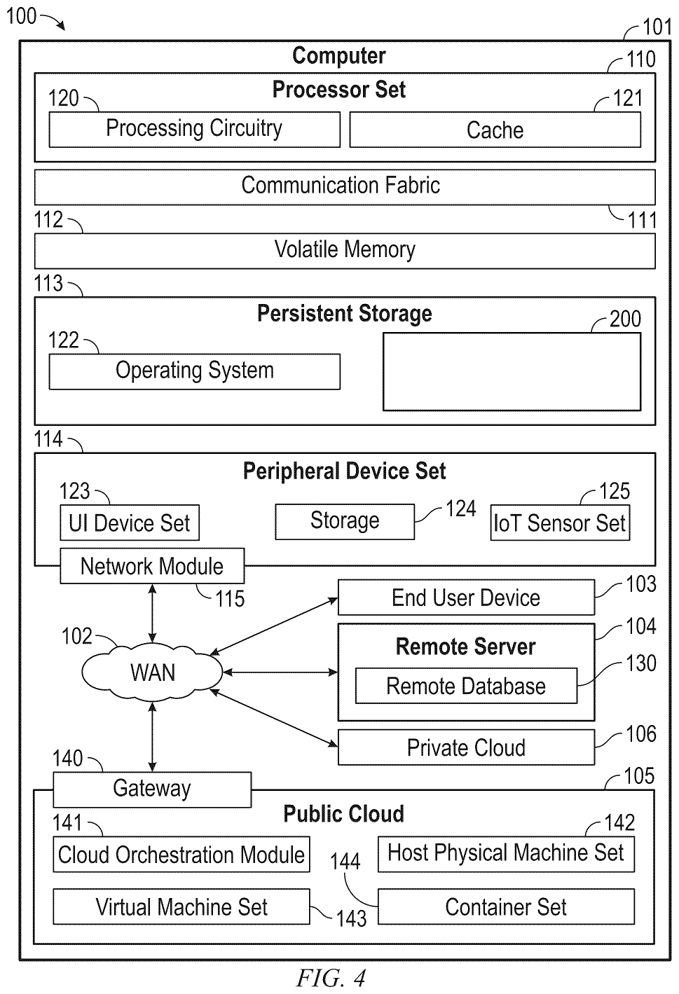

FIG. 5 is a flow diagram of a design process used in semiconductor design, manufacture, and/or test.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Generally, a complementary metal-oxide semiconductor (CMOS) based resistive processing unit for accelerating neural network training through asymmetric weight update is disclosed. Instead of using a current source or other complicated control circuit to symmetrically update the capacitor voltage, the disclosed RPU greatly simplifies the control circuit and updates the capacitor of the RPU asymmetrically. In one example embodiment, an RPU supports asymmetric weight updates with a high number of states and a high signal-to-noise ratio (SNR) to, for example, support a Tiki-Taka algorithm. Conventional devices have limitations due to inherent randomness originating from physical phenomena of switching.

### Capacitor-Based RPU Unit Cell Design

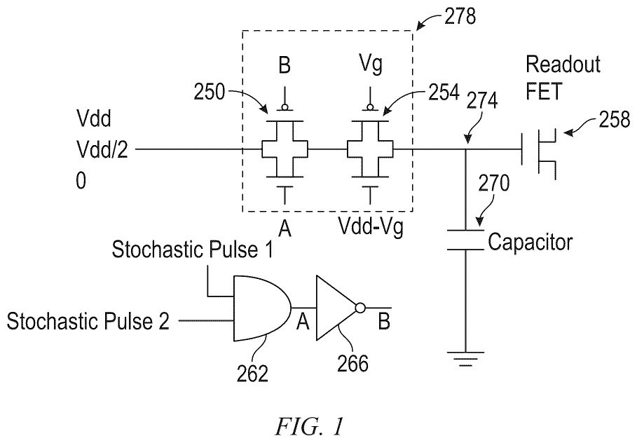

FIG. 1 is a circuit diagram for a capacitor-based RPU unit cell, in accordance with an exemplary embodiment. In one example embodiment, a capacitor 270 is connected to a voltage source through two transmission gates 250, 254 of a transmission gate circuit 278 and connected to a readout field-effect transistor (FET) 258. The voltage source provides a voltage selected from, for example, Vdd, 0 and Vdd/2 for a positive weight update, a negative weight update and an idle state, respectively. The transmission gate 250 is controlled by an AND gate 262 and an inverter 266. (The output of the AND gate 262 is connected to an input of the inverter 266 and a first gate of the transmission gate 250. The output of the inverter 266 is connected to a second gate of the transmission gate 250.) In one example embodiment, the input signals of the AND gate 262 are stochastic pulses produced by a stochastic pulse generator. When the stochastic pulses coincide, the transmission gate 250 turns on and passes the applied voltage. In one example embodiment, the AND gate 262 is not utilized and a single pulse is applied to the input of the inverter 266.

The transmission gate 254 is controlled by an analog voltage Vg. The transmission gate 254 essentially sets the resistance along the charging line 274 and, therefore, sets the resistance-capacitance (RC) time constant of the capacitor 270 and the update current of the capacitor 270. Once set, Vg is generally maintained at the same voltage. The update current is selected to support the number of states stored in the voltage on the capacitor 270. For example, from 10 to a few hundred different states (voltage levels) may be supported. In one or more embodiments, the number of states is estimated by dividing Vdd by dv, where dv is the change of capacitor voltage after each update and is determined by I*t/C, where t is the width of a stochastic pulse, C is the capacitance and/is controlled by Vdd, Vg and C. Vg can be anywhere between 0 to Vdd. For example, for 14 nm technology where Vdd=0.8V, Vg can be 0.2V or 0.4V.

The circuit of FIG. 1 operates with the Tiki-Taka algorithm. The design of the exemplary RPU is a pertinent hardware component to implement the Tiki-Taka and other algorithms, which significantly increases the speed of neural network training in an analog artificial intelligence (AI) accelerator.

During a positive weight update, Vdd is applied by the voltage source to the transmission gate circuit 278 and the two stochastic pulses are applied to the AND gate 262. The coincidence of the two stochastic pulses will turn on the transmission gate 250 to charge the capacitor 270. During the negative weight update, 0V is applied by the voltage source to the transmission gate circuit 278 and the two stochastic pulses are applied to the AND gate 262. The coincidence of the two stochastic pulses will turn on the transmission circuit 278 to discharge the capacitor 270.

During the idle state (such as during a readout of the capacitor 270, when updating is being conducted and the like), Vdd/2 is applied by the voltage source to the transmission gate circuit 278 to establish an equilibrium voltage on the charging line 274. During the idle state, the voltage of the capacitor will slowly drift towards the equilibrium voltage (Vdd/2) as current leaks through the transmission gate circuit 278.

During updating (where the analog weight is stored as a voltage on the capacitor 270), the voltage corresponding to the type of update (positive or negative) is first applied by the power source, the stochastic pulses are generated and, upon the completion of the charging/discharging of the capacitor 270, the voltage corresponding to the idle state is applied by the power source. During the readout of the voltage stored on the capacitor 270, a readout voltage is applied to the readout FET 258 and a current is generated (modulated) by the voltage of the capacitor 270. The value read indicates the value of the stored weight and may be used to configure the weights of a neural network. In one example embodiment, the weight stored on the capacitor 270 may be erased by simultaneously generating a first stochastic pulse and a second stochastic pulse until a voltage stored on the capacitor 270 reaches a reset voltage, such as the equilibrium voltage, zero volts and the like. Alternatively, the weight stored on the capacitor 270 may be erased by isolating the output of the AND gate 262 and applying a logic one to the input of the inverter 266 until a voltage stored on the capacitor 270 reaches the reset voltage.

### Capacitor-Based RPU Array

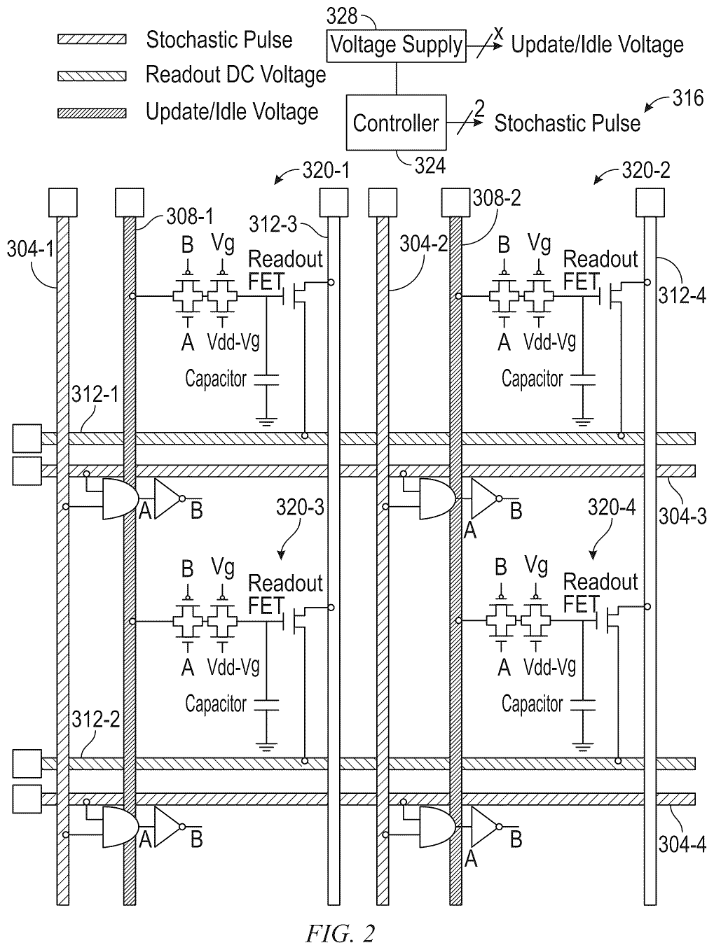

FIG. 2 is circuit diagram for a 2×2 capacitor-based RPU array, in accordance with an example embodiment. As illustrated in FIG. 2, the stochastic pulses are distributed to the RPUs via metal wires 304-1, 304-2, 304-3, 304-4, the power source is distributed to the RPUs via metal wires 308-1, 308-2 and the read signals for the readout field-effect transistor 258 are distributed to the RPUs via metal wires 312-1, 312-2, 312-3, 312-4. During the weight update, the coincidence of the stochastic pulses will turn-on multiple transmission gates 250, 254 in the array so the capacitor voltages are updated in parallel. During readout, the collection of all the readout current will perform, equivalently, a matrix multiplication in parallel.

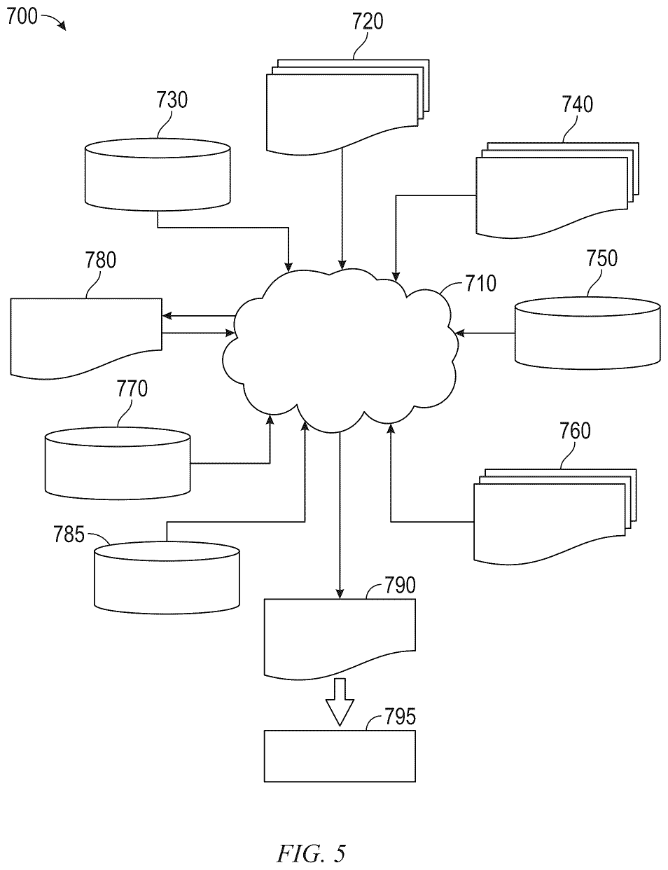

One or more embodiments further include a voltage supply 328; and a controller 324 that is coupled to the voltage supply. The controller 324 is configured to set a selectable first voltage source based on a given weight update for an array of capacitor-based resistive processing units; generate a first stochastic pulse and a second stochastic pulse to apply the given weight update to a weight capacitor based on the setting of the selectable first voltage source; and set the selectable first voltage source to indicate an idle state. Thus, the controller 324 and the voltage supply 328 are cooperatively configured to provide the voltages and stochastic pulses. The controller can include stochastic pulse generator(s) which can be coupled to suitable registers. Controller 324 carries out functions as defined herein; given the teachings and description of the functions herein, known control circuit technologies can be employed; e.g., multicycle or pipelined, hardwired or microprogrammed, using any suitable technology family (e.g., 7 nm CMOS, 5 NM CMOS, and the like). For example, the specified functions can be instantiated in logic circuitry as described below with respect to FIG. 5.

### Circuit Simulation for the Capacitor-Based RPU Unit Cell

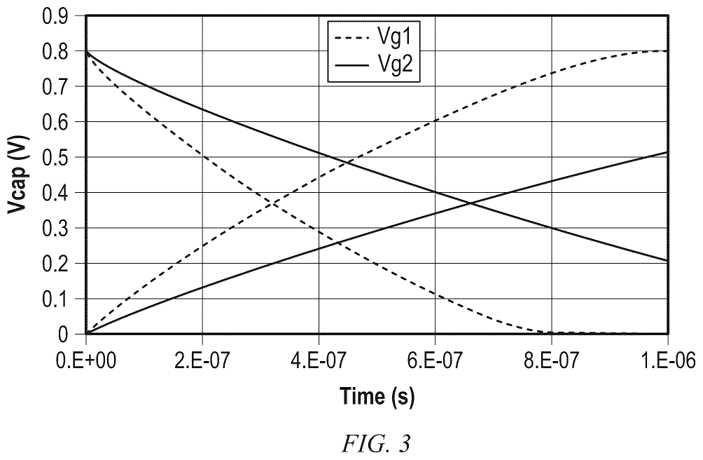

FIG. 3 illustrates the results of simulating the capacitor-based RPU of FIG. 1, in accordance with example embodiments. 14 nanometer (nm) low-power plus (14LPP) technology with deep trench (DT) capacitor was used in the simulation with a capacitor 270 of 100 femtofarad (fF). Positive and negative updates were simulated with two different gate voltages. The number of states for the capacitor was set to 1000 and the pulse width was 1 nanosecond (ns). The simulations are non-limiting and other embodiments can use different types of capacitors, different dimensions, different capacitance values, different technology nodes, etc.

Given the discussion thus far, it will be appreciated that, in general terms, an exemplary method, according to an aspect of the invention, includes the operations of setting a selectable first voltage source based on a given weight update for an array as described; generating a first stochastic pulse and a second stochastic pulse to apply the given weight update to a weight capacitor 270 based on the setting of the selectable first voltage source; and setting the selectable first voltage source to indicate an idle state.

In one example embodiment, a readout voltage for a readout field-effect transistor 258 is generated and a weight stored on the weight capacitor 270 is determined by determining a current that is modulated by a voltage of the weight capacitor 270.

In one example embodiment, a neural network is configured based on the determined stored weight.

In one example embodiment, the setting the selectable first voltage source based on the given weight update is set to generate Vdd for a positive update and is set to generate 0 volts for a negative update.

In one example embodiment, the setting the selectable first voltage source to indicate the idle state sets the selectable first voltage source to generate Vdd/2 for the idle state.

In one example embodiment, the weight capacitor 270 is erased by generating the first stochastic pulse and the second stochastic pulse until a voltage stored on the weight capacitor 270 reaches a reset voltage.

In aspect, a resistive processing unit to accelerate neural network training through asymmetric weight update comprises a readout field-effect transistor 258; a transmission gate circuit 278; a capacitor 270 coupled to the transmission gate circuit 278 and coupled to the readout field-effect transistor 258; and an inverter 266. The transmission gate circuit 278 is coupled to a selectable first voltage source and includes a first transmission gate 250 and a second transmission gate 254, and has at least one transistor gate coupled to a second voltage source. An input of the inverter 266 is coupled to at least one gate of the first transmission gate 250 and an output of the inverter 266 is coupled to at least one gate of the first transmission gate 250.

In one example embodiment, the resistive processing unit further includes an AND logic gate 262, an output of the AND logic gate 262 being coupled to the input of the inverter 266.

In one example embodiment, the selectable first voltage source provides one of three voltages, where the selectable first voltage source is configured to provide a first voltage for a positive weight update, the selectable first voltage source is configured to provide a second voltage for a negative weight update and the selectable first voltage source is configured to provide a third voltage for an idle state. A non-limiting example uses Vdd for a positive weight update, 0 volts for a negative weight update and Vdd/2 for an idle state. Generally, the voltage source is an analog voltage that can be any value between 0 volts and Vdd. Vdd, 0 volts, and Vdd/2 are exemplary voltages for positive/negative/idle states, but other values are contemplated. An advantage of an analog voltage is that it can also set/reset the capacitor voltage to any value efficiently. Thus, a non-limiting example uses Vdd, 0, and Vdd/2, but embodiments are not constrained to three voltages.

In one example embodiment, a first input of the AND gate 262 is driven by a first stochastic pulse and a second input of the AND gate 262 is driven by a second stochastic pulse.

In one example embodiment, the second voltage source provides an analog voltage Vg that sets an update current of the capacitor 270 by setting a resistance along a charging line 274 and setting a resistance-capacitance (RC) time constant of the capacitor 270.

In one aspect, a system comprises a plurality of first stochastic pulse lines 304-1, 304-2; a plurality of second stochastic pulse lines 304-3, 304-4; a plurality of update voltage lines 312-1, 312-2; a plurality of readout voltage lines 312-3, 312-4; an array 316 of capacitor-based resistive processing units 320-1, 320-2, 320-3, 320-4, each capacitor-based resistive processing unit 320-1, 320-2, 320-3, 320-4 connected to one of the plurality of first stochastic pulse lines 304-1, 304-2, one of the plurality of second stochastic pulse lines 304-3, 304-4, one of the plurality of update voltage lines 312-1, 312-2 and one of the plurality of readout voltage lines 312-3, 312-4; and a controller 324, the controller 324 configured to update capacitor voltages of the capacitor-based resistive processing units 320-1, 320-2, 320-3, 320-4 in parallel during a weight update phase and wherein a collection of readout current from the capacitor-based resistive processing units 320-1, 320-2, 320-3, 320-4 emulates a matrix multiplication operation during a readout phase.

The controller 324 can be further configured to cause the system to implement any one, some, or all of the method steps disclosed herein.

The skilled artisan will be generally familiar with conventional training of and inferencing with RPU arrays and, given the teachings herein, will be able to implement novel CMOS-based resistive processing units/arrays with asymmetric update.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as a system (see block 200) for semiconductor design and/or control of semiconductor fabrication (see FIG. 5). In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Exemplary Design Process Used in Semiconductor Design, Manufacture, and/or Test

One or more embodiments make use of computer-aided semiconductor integrated circuit design simulation, test, layout, and/or manufacture. In this regard, FIG. 5 shows a block diagram of an exemplary design flow 700 used for example, in semiconductor IC logic design, simulation, test, layout, and manufacture. Design flow 700 includes processes, machines and/or mechanisms for processing design structures or devices to generate logically or otherwise functionally equivalent representations of design structures and/or devices, such as those that can be analyzed using techniques disclosed herein or the like. The design structures processed and/or generated by design flow 700 may be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 700 may vary depending on the type of representation being designed. For example, a design flow 700 for building an application specific IC (ASIC) may differ from a design flow 700 for designing a standard component or from a design flow 700 for instantiating the design into a programmable array, for example a programmable gate array (PGA) or a field programmable gate array (FPGA) offered by Altera® Inc. or Xilinx® Inc.

FIG. 5 illustrates multiple such design structures including an input design structure 720 that is preferably processed by a design process 710. Design structure 720 may be a logical simulation design structure generated and processed by design process 710 to produce a logically equivalent functional representation of a hardware device. Design structure 720 may also or alternatively comprise data and/or program instructions that when processed by design process 710, generate a functional representation of the physical structure of a hardware device. Whether representing functional and/or structural design features, design structure 720 may be generated using electronic computer-aided design (ECAD) such as implemented by a core developer/designer. When encoded on a gate array or storage medium or the like, design structure 720 may be accessed and processed by one or more hardware and/or software modules within design process 710 to simulate or otherwise functionally represent an electronic component, circuit, electronic or logic module, apparatus, device, or system. As such, design structure 720 may comprise files or other data structures including human and/or machine-readable source code, compiled structures, and computer executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 710 preferably employs and incorporates hardware and/or software modules for synthesizing, translating, or otherwise processing a design/simulation functional equivalent of components, circuits, devices, or logic structures to generate a Netlist 780 which may contain design structures such as design structure 720. Netlist 780 may comprise, for example, compiled or otherwise processed data structures representing a list of wires, discrete components, logic gates, control circuits, I/O devices, models, etc. that describes the connections to other elements and circuits in an integrated circuit design. Netlist 780 may be synthesized using an iterative process in which netlist 780 is resynthesized one or more times depending on design specifications and parameters for the device. As with other design structure types described herein, netlist 780 may be recorded on a machine-readable data storage medium or programmed into a programmable gate array. The medium may be a nonvolatile storage medium such as a magnetic or optical disk drive, a programmable gate array, a compact flash, or other flash memory. Additionally, or in the alternative, the medium may be a system or cache memory, buffer space, or other suitable memory.

Design process 710 may include hardware and software modules for processing a variety of input data structure types including Netlist 780. Such data structure types may reside, for example, within library elements 730 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 740, characterization data 750, verification data 760, design rules 770, and test data files 785 which may include input test patterns, output test results, and other testing information. Design process 710 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 710 without deviating from the scope and spirit of the invention. Design process 710 may also include modules for performing standard circuit design processes such as timing analysis, verification, design rule checking, place and route operations, etc.

Design process 710 employs and incorporates logic and physical design tools such as HDL compilers and simulation model build tools to process design structure 720 together with some or all of the depicted supporting data structures along with any additional mechanical design or data (if applicable), to generate a second design structure 790. Design structure 790 resides on a storage medium or programmable gate array in a data format used for the exchange of data of mechanical devices and structures (e.g. information stored in an IGES, DXF, Parasolid XT, JT, DRG, or any other suitable format for storing or rendering such mechanical design structures). Similar to design structure 720, design structure 790 preferably comprises one or more files, data structures, or other computer-encoded data or instructions that reside on data storage media and that when processed by an ECAD system generate a logically or otherwise functionally equivalent form of one or more IC designs or the like. In one embodiment, design structure 790 may comprise a compiled, executable HDL simulation model that functionally simulates the devices to be analyzed.

Design structure 790 may also employ a data format used for the exchange of layout data of integrated circuits and/or symbolic data format (e.g. information stored in a GDSII (GDS2), GL1, OASIS, map files, or any other suitable format for storing such design data structures). Design structure 790 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described herein (e.g.,. lib files). Design structure 790 may then proceed to a stage 795 where, for example, design structure 790: proceeds to tape-out, is released to manufacturing, is released to a mask house, is sent to another design house, is sent back to the customer, etc.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A resistive processing unit to accelerate neural network training through asymmetric weight update, comprising:
a readout field-effect transistor;
a transmission gate circuit, the transmission gate circuit being coupled to a selectable first voltage source and including:
a first transmission gate; and
a second transmission gate, having at least one transistor gate coupled to a second voltage source;
a capacitor coupled to the transmission gate circuit and coupled to the readout field-effect transistor; and
an inverter, an input of the inverter being coupled to at least one gate of the first transmission gate and an output of the inverter being coupled to at least one gate of the first transmission gate.

2. The resistive processing unit of claim 1, further comprising an AND logic gate, an output of the AND logic gate being coupled to the input of the inverter.

3. The resistive processing unit of claim 1, wherein the selectable first voltage source provides one of three voltages, where the selectable first voltage source is configured to provide a first voltage for a positive weight update, the selectable first voltage source is configured to provide a second voltage for a negative weight update and the selectable first voltage source is configured to provide a third voltage for an idle state.

4. The resistive processing unit of claim 1, wherein a first input of the AND gate is driven by a first stochastic pulse and second input of the AND gate is driven by a second stochastic pulse.

5. The resistive processing unit of claim 1, wherein the second voltage source provides an analog voltage Vg that sets an update current of the capacitor by setting a resistance along a charging line and setting a resistance-capacitance (RC) time constant of the capacitor.

6. A method comprising:
setting a selectable first voltage source based on a given weight update for an array of capacitor-based resistive processing units, each capacitor-based resistive processing unit connected to one of a plurality of first stochastic pulse lines, one of a plurality of second stochastic pulse lines, one of a plurality of update voltage lines and one of a plurality of readout voltage lines, each capacitor-based resistive processing unit comprising a readout field-effect transistor; a transmission gate circuit, the transmission gate circuit being coupled to a selectable first voltage source and including: a first transmission gate; and a second transmission gate, having at least one transistor gate coupled to a second voltage source; a capacitor coupled to the transmission gate circuit and coupled to the readout field-effect transistor; and an inverter, an input of the inverter being coupled to at least one gate of the first transmission gate and an output of the inverter being coupled to at least one gate of the first transmission gate;
generating a first stochastic pulse and a second stochastic pulse to apply the given weight update to a weight capacitor based on the setting of the selectable first voltage source; and
setting the selectable first voltage source to indicate an idle state.

7. The method of claim 6, further comprising generating a readout voltage for a readout field-effect transistor and determining a weight stored on the weight capacitor by determining a current that is modulated by a voltage of the weight capacitor.

8. The method of claim 6, further comprising configuring a neural network based on the determined stored weight.

9. The method of claim 6, wherein the setting the selectable first voltage source based on the given weight update is set to generate a voltage Vdd for a positive update and is set to generate 0 volts for a negative update.

10. The method of claim 6, wherein the setting the selectable first voltage source to indicate the idle state sets the selectable first voltage source to generate a voltage Vdd/2 for the idle state.

11. The method of claim 6, further comprising erasing the weight capacitor by generating the first stochastic pulse and the second stochastic pulse until a voltage stored on the weight capacitor reaches a reset voltage.

12. A system comprising:
a plurality of first stochastic pulse lines;
a plurality of second stochastic pulse lines;
a plurality of update voltage lines;
a plurality of readout voltage lines;
an array of capacitor-based resistive processing units, each capacitor-based resistive processing unit connected to one of the plurality of first stochastic pulse lines, one of the plurality of second stochastic pulse lines, one of the plurality of update voltage lines and one of the plurality of readout voltage lines, each capacitor-based resistive processing unit comprising:
a readout field-effect transistor;
a transmission gate circuit, the transmission gate circuit being coupled to a selectable first voltage source and including:
a first transmission gate; and
a second transmission gate, having at least one transistor gate coupled to a second voltage source;
a weight capacitor coupled to the transmission gate circuit and coupled to the readout field-effect transistor; and
an inverter, an input of the inverter being coupled to at least one gate of the first transmission gate and an output of the inverter being coupled to at least one gate of the first transmission gate; and
a controller, the controller configured to update capacitor voltages of the capacitor-based resistive processing units in parallel during a weight update phase and wherein a collection of readout current from the capacitor-based resistive processing units emulates a matrix multiplication operation during a readout phase.

13. The system of claim 12, the operations further comprising generating a readout voltage for each readout field-effect transistor and determining a weight stored on at least one of the weight capacitors by determining a current that is modulated by a voltage of the weight capacitor.

14. The system of claim 12, the operations further comprising configuring a neural network based on the determined stored weights.

15. The system of claim 12, wherein the setting the selectable first voltage source based on the given weight update is set to generate a voltage Vdd for a positive update and is set to generate 0 volts for a negative update.

16. The system of claim 12, wherein the setting the selectable first voltage source to indicate the idle state sets the selectable first voltage source to generate a voltage Vdd/2 for the idle state.

17. The system of claim 12, the operations further comprising erasing at least one of the weight capacitors by generating the first stochastic pulse and the second stochastic pulse until a voltage stored on the at least one of the weight capacitors reaches a reset voltage.
